(19) United States
(12) Patent Application Publication
(10) Pub. No.: US 2015/0076509 A1
(43) Pub. Date: Mar. 19, 2015

(54) SEMICONDUCTOR DEVICE WITH BUFFER LAYER MADE OF NITRIDE SEMICONDUCTOR

(71) Applicant: FUJITSU LIMITED, Kawasaki-shi (JP)

(72) Inventors: TETSURO ISHIGURO, Kawasaki (JP); JUNJI KOTANI, Atsugi (JP); NORIKAZU NAKAMURA, Sagamihara (JP)

(21) Appl. No.: 14/455,218

(22) Filed: Aug. 8, 2014

(30) Foreign Application Priority Data
Sep. 19, 2013 (JP) 2013-194412

(51) Int. Cl. H01L 29/778; H01L 21/02; H01L 29/205; H01L 29/207; H01L 29/20; H01L 29/66

(52) U.S. Cl. CPC H01L 29/7787; H01L 29/2003; H01L 29/66462; H01L 29/205; H01L 29/207; H01L 21/0254; H01L 21/02458
USPC 257/76; 438/172

(57) ABSTRACT

A semiconductor device includes a buffer layer made of nitride semiconductor on a substrate, a first semiconductor layer made of nitride semiconductor on the buffer layer, a second semiconductor layer made of nitride semiconductor on the first semiconductor layer, and a gate electrode, a source electrode, and a drain electrode formed on the second semiconductor layer, wherein the buffer layer has elements doped therein that include both an element selected from a group consisting of C, Mg, Fe, and Co and an element selected from a group consisting of Si, Ge, Sn, and O.

### CROSS-REFERENCE TO RELATED APPLICATIONS

The present application is based upon and claims the benefit of priority from the prior Japanese Patent Application No. 2013-194412 filed on Sep. 19, 2013, with the Japanese Patent Office, the entire contents of which are incorporated herein by reference.

### FIELD

The disclosures herein relate to a semiconductor device and a method of manufacturing a semiconductor device.

### BACKGROUND

Nitride semiconductor has high saturated electron velocity and a wide band gap. With a focus on such characteristics, study has been underway on the application of nitride semiconductor to high voltage and high power semiconductor devices. GaN, which is nitride semiconductor, has a band gap of 3.4 eV, which is higher than the Si band gap (which is 1.1 eV) and the GaAs band gap (which is 1.4 eV). Also, GaN has high breakdown field strength. Nitride semiconductor such as GaN is thus extremely promising as semiconductor device material for use in a power supply apparatus that operates with high voltage and produces high power.

In respect of semiconductor devices using nitride semiconductor, field-effect transistors, especially high electron mobility transistors (i.e., HEMT), have been described in a large number of reports. Attention to GaN HEMTs is mainly directed to AlGaN/GaN HEMTs that use GaN as an electron transit layer and AlGaN as an electron supply layer. In AlGaN/GaN HEMTs, strain occurs in AlGaN due to a difference in lattice constant between GaN and AlGaN. Difference in the piezoelectric polarization generated in this manner and self-induced polarization in AlGaN results in the generation of high-density 2DEG (i.e., two dimensional electron gas). Because of this, there is an expectation that a highly efficient switching device and a high-voltage power device can be obtained. From the circuit design and safety point of view, it is desirable to provide a nitride semiconductor transistor that has a normally-off characteristic.

A nitride semiconductor transistor is manufactured by forming an electron channel layer and an electron supply layer of nitride semiconductor on a substrate by use of MOVPE (i.e., metal organic vapor phase epitaxy). The substrate may be made of sapphire, silicon carbide (SiC), gallium nitride (GaN), silicon (Si), etc. The use of a silicon substrate achieves significant cost reduction through provision of an inexpensive, large substrate.

However, silicon used in a silicon substrate has a lattice constant and a thermal expansion constant that are significantly different from those of nitride semiconductor that forms nitride semiconductor layers. Due to a large difference in lattice constant and thermal expansion constant between silicon and nitride semiconductor, the silicon substrate may easily develop distortion, and the nitride semiconductor layers may easily suffer cracks. It is thus difficult to increase the thickness of nitride semiconductor layers. Prohibition against increasing the thickness of nitride semiconductor layers hampers the efforts toward improving the breakdown voltage of semiconductor devices and toward reducing dislocation density. This undermines the original purpose of using nitride semiconductor, which is to improve the breakdown voltage of semiconductor devices.

Methods tor increasing the thickness of nitride semiconductor layers while avoiding the occurrence of substrate distortion and cracks include forming an AlGaN buffer structure with stepwise Al compositions and forming an SLS (i.e., strained layer superlattice) buffer structure. To be more specific, a buffer layer having such a buffer structure is formed on a silicon substrate, and, then, an electron channel layer and an electron supply layer are formed by use of nitride semiconductor on the buffer layer. The buffer layer having the AlGaN buffer structure with stepwise Al compositions has a structure in which a plurality or AlGaN layers are stacked one over another with respective, different Al compositions. The buffer layer having the SLS buffer structure has a structure in which GaN thin films and AlN thin films are repeatedly stacked one over another.

A buffer layer having either one of these buffer structures has large compressive strain in the electron channel layer made of GaN, which cancels strong tensile strain that is generated in the entirety of nitride semiconductor layers during the temperature dropping process following film formation. As a result, distortion and cracks are suppressed.

The buffer structures described above inevitably have complex structures, resulting in an increase in the time length required to form the buffer layer, which in turn leads to a drop in throughput. Further, the amount of raw materials inclusive of expensive organometallic materials is increased, which results in manufactured semiconductor devices being more expensive.

[Patent Document 1] Japanese Laid-open Patent Publication No. 2012-023314

[Patent Document 2] Japanese Laid-open Patent Publication No. 2007-067077

### SUMMARY

According to an aspect of the embodiment, a semiconductor device includes a buffer layer made of nitride semiconductor on a substrate, a first semiconductor layer made of nitride semiconductor on the buffer layer, a second semiconductor layer made of nitride semiconductor on the first semiconductor layer, and a gate electrode, a source electrode, and a drain electrode formed on the second semiconductor layer, wherein the buffer layer has elements doped therein that include both an element selected from a group consisting of C, Mg, Fe, and Co and an element selected from a group consisting of Si, Ge, Sn, and O.

According to an aspect of the embodiment, a method of manufacturing a semiconductor device includes forming a buffer layer made of nitride semiconductor on a substrate, forming a first semiconductor layer made of nitride semiconductor on the buffer layer, forming a second semiconductor layer made of nitride semiconductor on the first semiconductor layer, and forming a gate electrode, a source electrode, and a drain electrode on the second semiconductor layer, wherein the buffer layer has elements doped therein that include both an element selected from a group consisting of C, Mg, Fe, and Co and an element selected from a group consisting of Si, Ge, Sn, and O.

The object and advantages of the embodiment will be realized and attained by means of the elements and combinations particularly pointed out in the claims. It is to be understood that both the foregoing general description and the following detailed description are exemplary and explanatory and are not restrictive of the invention, as claimed.

### BRIEF DESCRIPTION OF DRAWINGS

FIGS. 1A and 1B are drawings illustrating the warpage of a substrate curved upward at the edges generated due to thermal contraction following the formation of a GaN layer;

FIG. 2 is a drawing illustrating a structure of a test material produced for studying warpage;

FIG. 3 is a drawing illustrating the relationship between the density of Si doped In a buffer layer and a warpage of the substrate curved downward at the edges;

FIG. 4 is a drawing illustrating correlation between the density of Si doped in the buffer layer and Twist obtained by an XRC method;

FIG. 5 is a drawing illustrating the relationship between the density of Si doped in a buffer layer and a warpage of the substrate curved downward at the edges;

FIG. 6 is a drawing illustrating the structure of the semiconductor device according to the first embodiment;

FIG. 7 is a drawing illustrating C and Si doped in the semiconductor device according to the first embodiment;

FIGS. 8A through 8C are drawings illustrating the steps of manufacturing the semiconductor device according to the first embodiment;

FIG. 9 is a drawing illustrating the structure of the semiconductor device according to a second embodiment;

FIG. 10 is a drawing illustrating C and Si doped in the semi conductor device according to the second embodiment;

FIG. 11 is a drawing illustrating a semiconductor device in a discrete package according to a third embodiment;

FIG. 12 is a circuit diagram of a power supply apparatus according to the third embodiment; and

FIG. 13 is a drawing illustrating the structure of a high-power amplifier according to the third embodiment.

### DESCRIPTION OF EMBODIMENTS

In the following, embodiments will be described by referring to the accompanying drawings. The same or similar elements are referred to by the same or similar numerals.

### First Embodiment

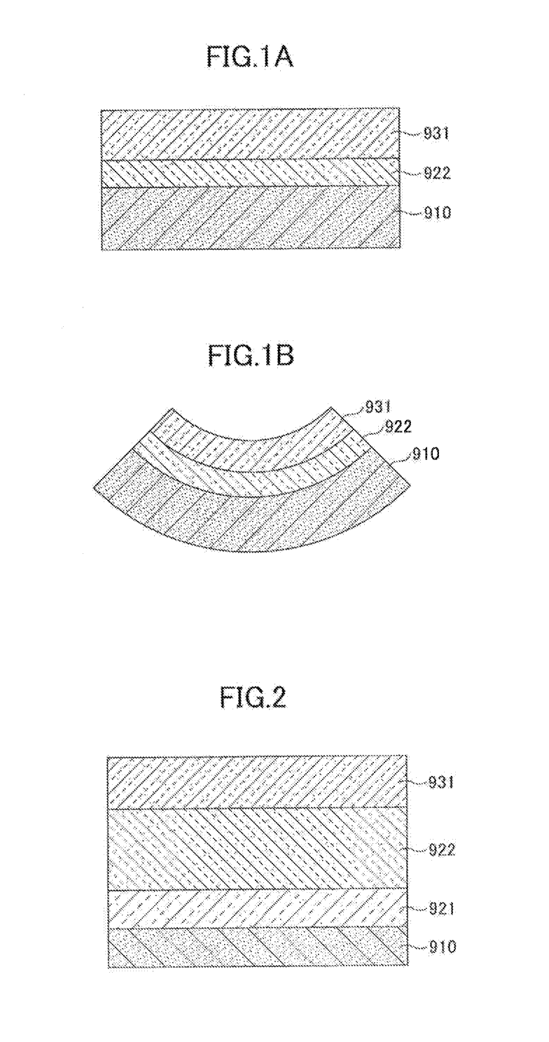

A description will be first given of distortion of a silicon substrate. As illustrated in FIG. 1A, a buffer layer 922 is formed on a silicon substrate 910, and a GaN layer 931 is formed on the buffer layer 922 by use of MOVPE. In such a case, as illustrated in FIG. 1B, the silicon substrate 910 is warped upward at the edges due to thermal contraction or the like at the time of a temperature drop. A warpage of the silicon substrate 910 is dependent on the thickness of the GaN layer 931. As the thickness of the GaN layer 931 increases, the warpage of the silicon substrate 910 also increases, which may result in cracks or the like being created in the GaN layer 931. Further, the warping of the silicon substrate 910 makes it difficult for a vacuum chuck or the like provided in a semiconductor manufacturing apparatus to carry the silicon substrate 910. Such warping also prevent a desired exposure pattern from being formed at the time of exposure. Consequently, manufacturing a semiconductor device may become impossible, or a semiconductor device having desired characteristics cannot be manufactured. Moreover, cracks in the GaN layer 931 make the semiconductor device useless.

Study was conducted with respect to a warpage of the silicon substrate 910 by manufacturing a test sample having the structure illustrated in FIG. 2. To be more specific, a nucleation layer 921, a buffer layer 922, and a GaN layer 931 were formed one over another on a silicon substrate 910 to produce a test sample, which was subjected to study. It may be noted that an AlGaN layer serving as an electron channel layer may be formed on the GaN layer 931 of this test sample, followed by forming a gate electrode, a source electrode, and a drain electrode on the AlGaN layer, thereby producing a semiconductor device in which the GaN layer 931 serves as an electron channel layer. The nucleation layer 921 is formed of AlN. The buffer layer 922 is formed of AlGaN.

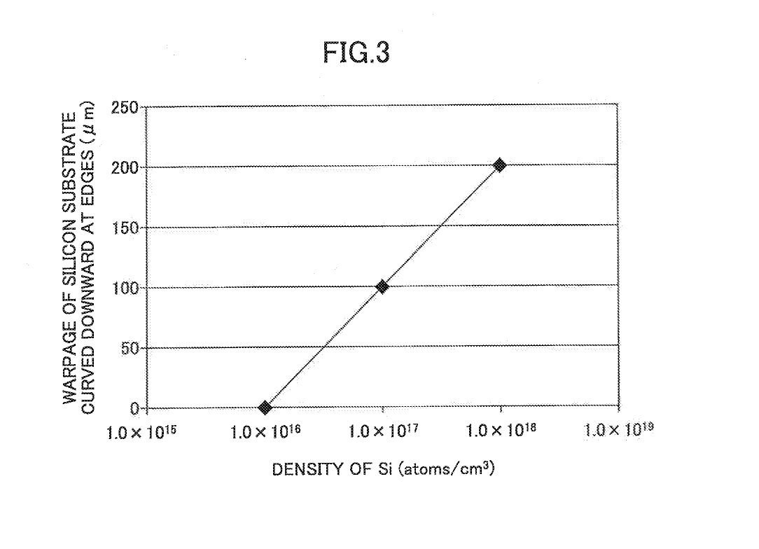

In such a test sample, the density of Si doped in the buffer layer 922 was changed to monitor a warpage of the silicon substrate 910 curved downward at the edges. FIG. 3 illustrates the results. As illustrated in FIG. 3, an increase in the density of Si doped in the buffer layer 922 results in a warpage of the silicon substrate 910 being increased.

The density of Si doped in the buffer layer 922 is in linear relationship with the warpage of the silicon substrate 910 curved downward at the edges. Accordingly, the density of Si doped in the buffer layer 922 may be adjusted in response to the thickness of the GaN layer 931 serving as an electron channel layer, thereby cancelling the warpage of the GaN layer 9 31 curved upward at the edges due to thermal contraction with the warpage curved downward at the edges due to the doping of Si into the buffer layer 922. With this arrangement, a warpage of the silicon substrate 910 is suppressed to suppress the occurrence of cracks or the like in the nitride semiconductor layers.

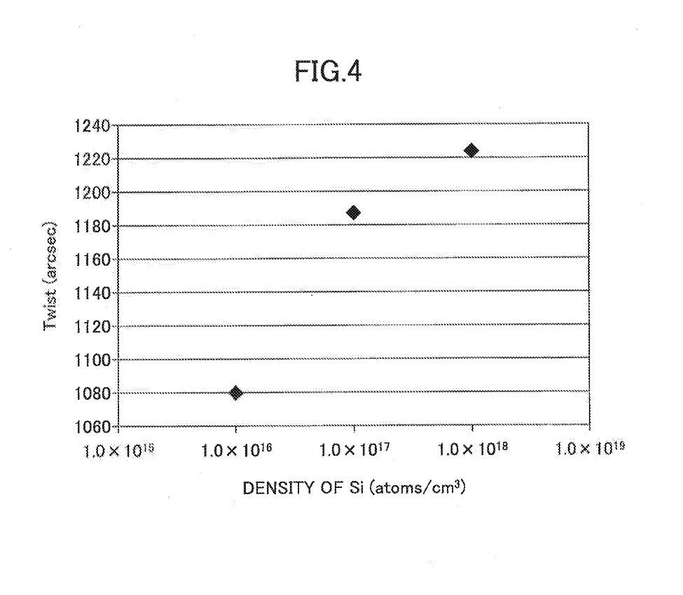

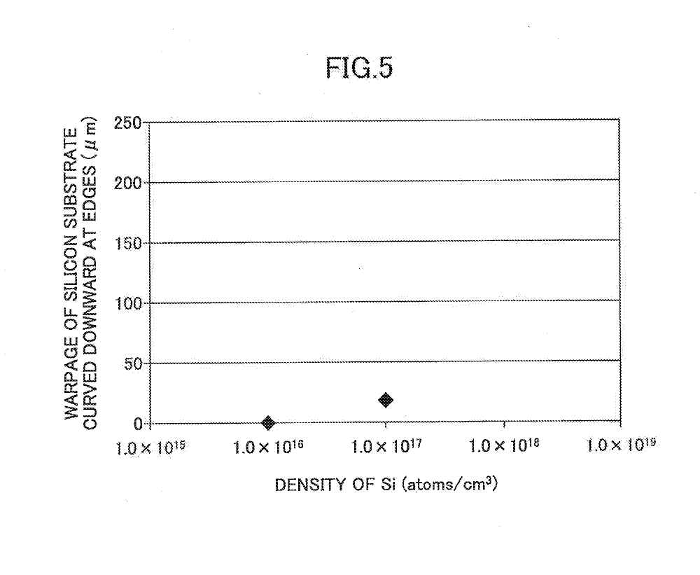

FIG. 4 is a drawing illustrating the relationship between the density of Si doped in she buffer layer 922 and the Twist value in the GaN layer 931 measured by use of the XRC (i.e., X-ray rocking curve) method. The Twist value is an indicator of dislocation density. The larger the Twist value, the larger the dislocation density is. As illustrated in FIG. 4, an increase in the density of Si doped in the buffer layer 922 results in an increase in the Twist value, i.e., an increase in dislocation density. Accordingly, doping Si into AlGaN of the buffer layer 922 serves to increase dislocation. As a result, the buffer layer 922 mitigates stress that is generated in the GaN layer 931 during the temperature dropping period, which is believed to have the effect of suppressing a warpage of the silicon substrate 910.

FIG. 5 is a drawing illustrating the relationship between the density of Si doped in the buffer layer 922 and a warpage of the silicon substrate 910 curved downward at the edges when the buffer layer 922 is made of GaN. Even in the case of the buffer layer 922 being made of GaN, an increase in the density of Si doped in the buffer layer 922 causes a warpage of the silicon substrate 910 curved downward at the edges so be increased. Such a warpage, however, is smaller than in the case of the buffer layer 922 being made of AlGaN. It follows that AlGaN is preferable over GaN as a material for forming the buffer layer 922.

Low resistance in the buffer layer 922 is not preferable because such low resistance serves to increase a leak current flowing in a vertical direction substantially perpendicular to the silicon substrate 910. In the present embodiment, thus, C (carbon) is doped in the buffer layer 922 to increase the resistance of the buffer layer 922. With this arrangement, the leak current flowing in the vertical direction is reduced, thereby achieving satisfactory semiconductor device characteristics.

In the present embodiment, both Si and C are doped in the buffer layer to suppress the warpage of a silicon substrate or the like and the occurrence of cracks in nitride semiconductor layers and also to achieve satisfactory semiconductor device characteristics. The present embodiment does not require formation of the strained layer superlattice structure or the like, and, thus, can manufacture a semiconductor device at low cost.

### Semiconductor Device

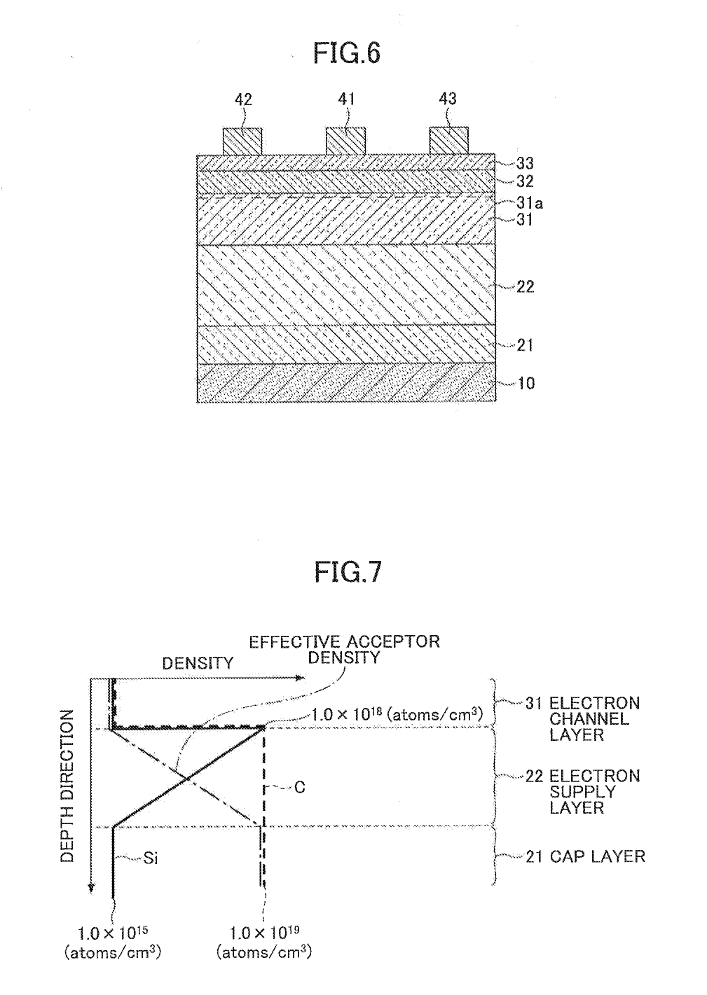

In the following, a semiconductor device according to a first embodiment will be described. The semiconductor device of the present embodiment has a structure in which nitride semiconductor layers are stacked one over another on a silicon substrate 10 as illustrated in FIG. 6. To be more specific, a nucleation layer 21 is formed on the silicon substrate 10, and a buffer layer 22 is formed on the nucleation layer 21, with an electron channel layer 31, an electron supply layer 32, and a cap layer 33 being stacked one over another on the buffer layer 22. Further, a gate electrode 41, a source electrode 42, and a drain electrode 43 are formed on the cap layer 33.

The nucleation layer 21 is formed of AlN. The buffer layer 22 is formed of AlGaN (AlₓGa₁₋ₓN). The electron channel layer 31 is formed of GaN, and the electron supply layer 32 is formed of AlGaN (Al_{y}Ga_{1-y}N), with the cap layer 33 being formed of n-GaN. With this arrangement, 2DEG 31a is generated near the interface between the electron channel layer 31 and the electron supply layer 32. It may be noted that a SiC substrate or a sapphire substrate may be used in place of the silicon substrate 10. There may be a case in which the cap layer 33 is not formed.

As illustrated in FIG. 7, both Si and C are doped in the buffer layer 22 in the present embodiment. The density of C doped in the buffer layer 22 is substantially homogeneous at 1.0×10¹⁹ atoms/cm³. Further, the density of Si doped in the buffer layer 22 gradually increases from the interface with the nucleation layer 21 situated toward the silicon substrate 10 to the interface with the electron channel layer 31.

The density of Si in the buffer layer 22 in the immediate proximity of the interface with the nucleation layer 21 is 1.0×10¹⁵ atoms/cm³. The density of Si gradually increases toward the electron channel layer 31, and is 1.0×10¹⁸ atoms/cm³ in the immediate proximity of the interface with the electron channel layer 31. In the manner as described above, Si is doped in the buffer layer 22 such that the density thereof gradually increases from the interface with the nucleation layer 21 to the interface with the electron channel layer 31. This arrangement serves to gradually decrease effective acceptor density that contributes to an increase in resistance.

If Si is not doped in the buffer layer 22, current collapse is likely to happen due to the presence of C doped in the buffer layer 22 in the proximity of the interface with the electron channel layer 31. In the present embodiment, however, the density of Si in the buffer layer 22 is high in the vicinity of the interface with the electron channel layer 31, which serves to decrease effective acceptor density that contributes to an increase in resistance, thereby suppressing the occurrence of current collapse. With this arrangement, the characteristics of the semiconductor device can further be improved. Namely, voltage tolerance is improved and the occurrence of current collapse is suppressed in the semiconductor device of the present embodiment, thereby achieving satisfactory semiconductor device characteristics.

In the present embodiment, the buffer layer 22 is made into a film of desired high resistance by preferably setting the density of C doped in the buffer layer 22 to no lower than 1.0×10¹⁸ atoms/cm³ and no higher than 1.0×10²⁰ atoms/cm³. Further, the density of Si in the area of the buffer layer 22 where the density of Si is highest, i.e., in the immediate proximity of the interface with the electron channel layer 31, is preferably set to no lower than 1.0×10¹⁶ atoms/cm³ and no higher than 1.0×10¹⁹ atoms/cm³.

In the semiconductor device of the present embodiment, the density of C doped in the nucleation layer 21 is 1.0×10¹⁹ atoms/cm³, and the density of Si doped in the nucleation layer 21 is 1.0×10¹⁵ atoms/cm³. Alternatively, the present embodiment may be modified such that both C and Si are doped in either one of the nucleation layer 21 and the buffer layer 22.

Further, the present embodiment has been described with reference to a case in which C and Si are doped in the buffer layer 22. Alternatively, Mg, Fe, Co or the like may be doped in place of C, and Ge, Sn, O or the like may be doped in place of Si.

### Method of Manufacturing Semiconductor Device

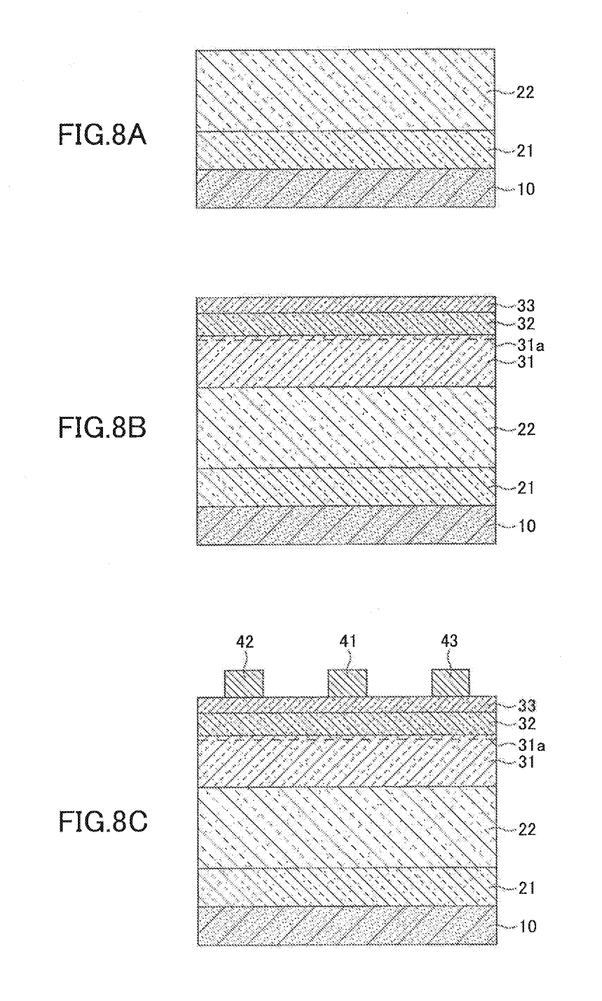

In the following, a method of manufacturing a semiconductor device according to the present embodiment will be described with reference to FIG. 8. The method of manufacturing a semiconductor device of the present embodiment forms nitride semiconductor layers through epitaxial growth on the silicon substrate 10 serving as a substrate. The method of forming nitride semiconductor layers through epitaxial growth includes MOVPE and MBE (i.e., molecular beam epitaxy).

In the explanation of the present embodiment, a description will be given of a case in which nitride semiconductor layers are formed by MOVPE. When nitride semiconductor layers are formed by MOVPE, TMA (i.e., trimethyl aluminum) is used as raw material gas for Al, and TMG (i.e., trimethyl gallium) is used as raw material gas for Ga, with NH₃ (i.e., ammonia) being used as raw material gas for N. Further, carrier gas such as H₂ may be supplied when supplying raw material gases.

As illustrated in FIG. 8A, the nucleation layer 21 and the buffer layer 22 are successively formed by use of nitride semiconductor on the silicon substrate 10.

The nucleation layer 21 is an AlN film having a thickness of a few tens of nanometers to a few hundreds of nanometers, which may be 200 nm in thickness, for example. The buffer layer 22 is made of AlₓGa₁₋ₓN, and has a thickness of 500 nm to 1000 nm. Since the electron channel layer 31 is formed of GaN or the like on the buffer layer 22, the value of x is preferably larger than or equal to 0 and smaller than or equal to 0.5, and is more preferably larger than 0 and smaller than or equal to 0.5. In the present embodiment, the buffer layer 22 is made of Al_{0.3}Ga_{0.7}N, for which the value of x is 0.3.

It may be noted that the buffer layer 22 is formed on the nucleation layer 21 made of AlN, and the electron channel layer 31 made of GaN is formed on the buffer layer 22. In order to provide a matching lattice constant, the buffer layer 22 may be formed such that the Al composition ratio thereof, i.e., the value of x, gradually decreases from the proximity of the interface with the nucleation layer 21 to the proximity of the interface with the electron channel layer 31. Alternatively, the buffer layer 22 may be formed with two or more layers of AlGaN having respective, different composition ratios. In this case, a layer closer to the electron channel layer 31 preferably has a smaller Al composition ratio than a layer closer to the nucleation layer 21.

In the present embodiment, C is homogeneously doped in the buffer layer 22. The density of doped C is 1.0×10¹⁹ atoms/cm³. Further, the density of Si doped in the buffer layer 22 gradually increases from the interface with the nucleation layer 21 situated toward the silicon substrate 10 to the interface with the electron channel layer 31. The density of Si in the buffer layer 22 in the immediate proximity of the interface with the nucleation layer 21 is 1.0×10¹⁵ atoms/cm³. The density of Si gradually increases toward the electron channel layer 31, and is 1.0×10¹⁸ atoms/cm³ in the immediate proximity of the interface with the electron channel layer 31.

At the time of forming the buffer layer 22, SiH₄ (monosilane) is supplied in addition to TMA, TMG, and NH₃ in order to dope a predetermined density of Si. Further, the conditions for growth of the buffer layer 22 may be adjusted to achieve auto-doping of C. CBr₄ (carbon tetrabromide) may be supplied as a dopant raw material for C.

The density of Si doped in the buffer layer 22 may linearly increase from the interface with the nucleation layer 21 to the interface with the electron channel layer 31. Alternatively, the density of Si may increase exponentially, or may increase in a stepwise manner.

As illustrated in FIG. 8B, the electron channel layer 31, the electron supply layer 32, and the cap layer 33 are stacked one over another on the buffer layer 22. Specifically, the electron channel layer 31 has a thickness of 500 nm to 1000 nm, and may be a GaN layer that is 1000 nm in thickness. The electron supply layer 32 may be approximately 20 nm in thickness and made of Al_{y}Ga_{1-y}N. The value of y is preferably 0.3 or smaller. In the present embodiment, Al_{0.2}Ga_{0.8}N is used. The cap layer 33 is approximately 5 nm in thickness and made of n-GaN. Si serving as n-type impurity is doped at predetermined density.

As illustrated in FIG. 8C, the source electrode 42 and the drain electrode 4 3 are formed on the cap layer 33, followed by forming the gate electrode 41 on the cap layer 33. Specifically, photoresist is applied on the cap layer 33, which is exposed to light and developed by an exposure apparatus, thereby forming a resist pattern (not shown) that has openings in the areas where the source electrode 42 and the drain electrode 43 are to be formed. A metal laminated film made of Ti/Al is then formed by vacuum vapor deposition. Immersion in organic solvent removes the metal laminated film formed on the resist pattern together with the resist pattern. The metal laminated film that is left after these processes forms the source electrode 42 and the drain electrode 43. After this, RTA (i.e., rapid thermal anneal) is performed to achieve ohmic contact with respect to the source electrode 42 and the drain electrode 43. In the metal laminated film made of Ti/Al, the thickness of the Ti film is approximately 100 nm, and the thickness of the Al film is approximately 300 nm.

After this, photoresist is applied again on the cap layer 33, which is exposed to light and developed by an exposure apparatus, thereby forming a resist pattern (not shown) that has an opening in the area where the gate electrode 41 is to be formed. A metal laminated film made of Ni/Au is then formed by vacuum vapor deposition. Immersion in organic solvent removes the metal laminated film formed on the resist pattern together with the resist pattern. The metal laminated film remaining after these processes forms the gate electrode 41. In the metal laminated film made of Ni/Au, the thickness of the Ni film is approximately 50 nm, and the thickness of the Au film is approximately 300 nm.

The manufacturing steps described above form the semiconductor device of the present embodiment.

### Second Embodiment

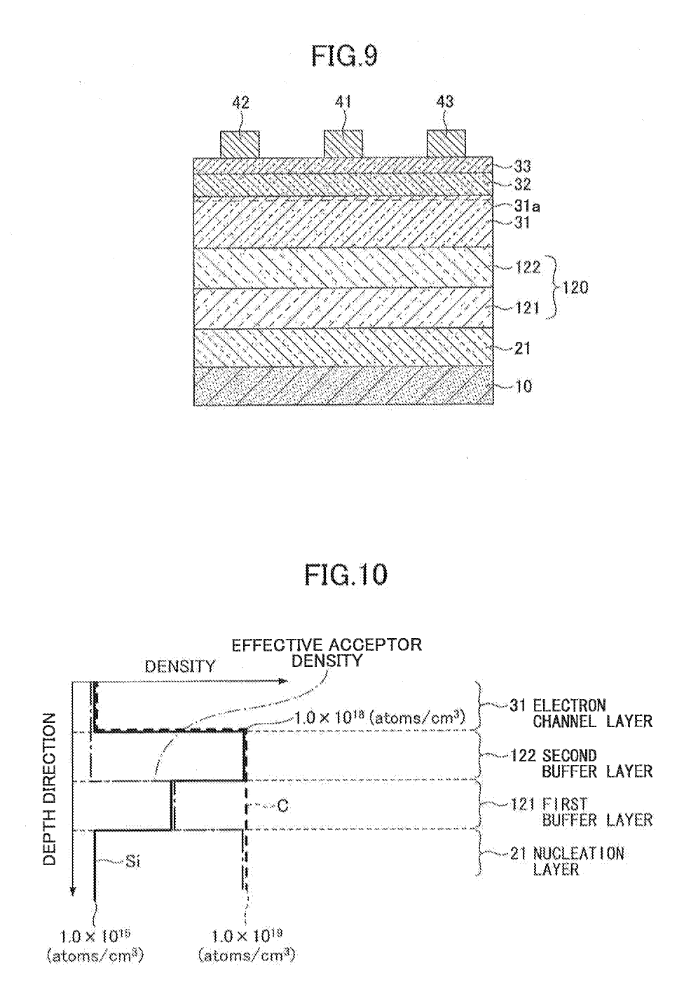

In the following, a second embodiment will be described. In the present embodiment, as illustrated in FIG. 9, a buffer layer 120 includes a first buffer layer 121 and a second buffer layer 122. In the present embodiment, the first buffer layer 121 and the second buffer layer 122 have different doped Si densities. As illustrated in FIG. 10, Si is doped at higher density in the second buffer layer 122 than in the first buffer layer 121. It may be noted that the density of C is approximately the same in the first buffer layer 121 and in the second buffer layer 122.

The first buffer layer 121 and the second buffer layer 122 are made of AlGaN, and may have different composition ratios. Alternatively, their composition ratios may be the same. In the case of composition ratios being different, the composition ratio of Al is preferably lower in the second buffer layer 122 than in the first buffer layer 121.

In the present embodiment, the density of C doped in the first buffer layer 121 and the second buffer layer 122 is 1.0×10¹⁹ atoms/cm³. The density of Si doped in she first buffer layer 121 is 3.0×10¹⁶ atoms/cm³, and the density of Si doped in the second buffer layer 122 is 1.0×10¹⁸ atoms/cm³.

### Third Embodiment

In the following, a third embodiment will be described. The present embodiment is directed to a semiconductor device, a power supply apparatus, and a high-frequency amplifier.

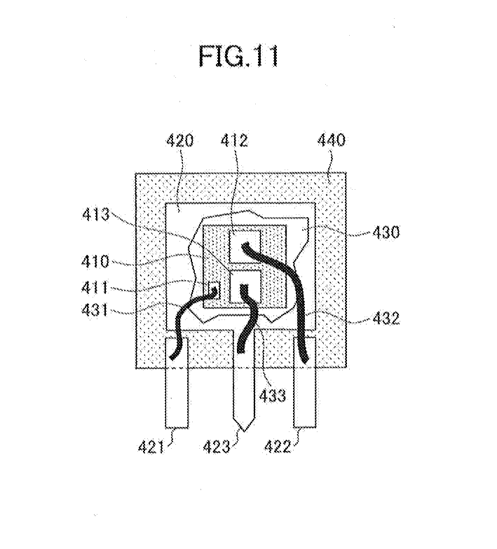

The semiconductor device according to the present embodiment is the semiconductor device of the first or second embodiment provided in a discrete package. Such a semiconductor device in a discrete package will be described with reference to FIG. 11. FIG. 11 illustrates the inner configuration of a semiconductor device in a discrete package. The placement of electrodes and the like may be different from those described in the first or second embodiment.

The semiconductor device manufactured in the first or second embodiment is cut into pieces to create a semiconductor chip 410 that is a HEMT made of GaN-based semiconductor materials. The semiconductor chip 410 is fixedly mounted on a leadframe 420 by use of a die attach agent 430 such as solder. The semiconductor chip 410 corresponds to the semiconductor device of the first or second embodiment.

A gate electrode 411 is connected to a gate lead 421 through a bonding wire 431, and a source electrode 412 is connected to a source lead 422 through a bonding wire 432. Further, a drain electrode 413 is connected to a drain lead 423 through a bonding wire 433. The bonding wires 431, 432, and 433 are made of metal material such as Al. In the present embodiment, the gate electrode 411 is a gate electrode pad, which is connected to the gate electrode 41 of the semiconductor device of the first or second embodiment. The source electrode 412 is a source electrode pad, which is connected to the source electrode 42 of the semiconductor device of the first or second embodiment. The drain electrode 413 is a drain electrode pad, which is connected to the drain electrode 43 of the semiconductor device of the first or second embodiment.

Resin-based encapsulation is then performed by use of mold resin 440 through the transfer mold method. In this manner, a semiconductor device provided in a discrete package in which a HEMT utilizing GaN-based semiconductor materials is embedded is manufactured.

In the following, a power supply apparatus and a high-frequency amplifier of the present embodiment will be described. The power supply apparatus and high-frequency amplifier of the present embodiment utilize the semiconductor device of the first or second embodiment.

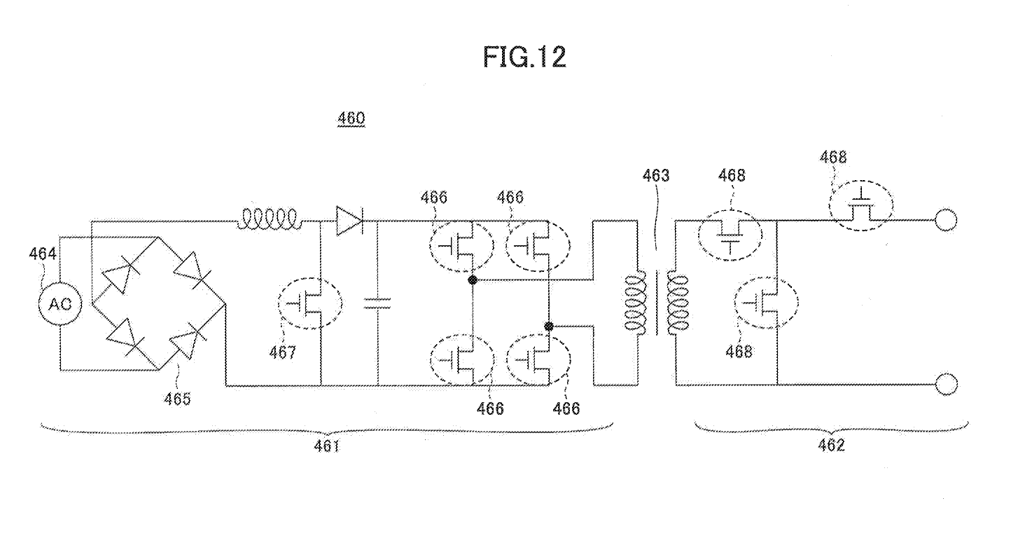

In the following, a description will be given of the power supply apparatus of the present embodiment by referring to FIG. 12. A power supply apparatus 460 of the present embodiment includes a primary-side high-voltage circuit 461, a secondary-side low-voltage circuit 462, and a transformer 463 situated between the primary-side high-voltage circuit 461 and the secondary-side low-voltage circuit 462. The primary-side circuit 461 includes an alternating-current power supply 464, a bridge rectifier circuit 465, a plurality (four in the example illustrated FIG. 12) of switching devices 466, and a switching device 467. The secondary-side circuit 462 includes a plurality (three in the example illustrated in FIG. 12) of switching devices 468. In the example illustrated in FIG. 12, the semiconductor device of the first or second embodiment is used as the switching devices 466 and 467. It may be noted that the switching devices 466 and 467 of the primary-side circuit 461 are preferably semiconductor devices with a normally-off characteristic. The switching devices 468 used in the secondary-side circuit 462 are silicon-based MISFETs (i.e., metal insulator semiconductor field effect transistors).

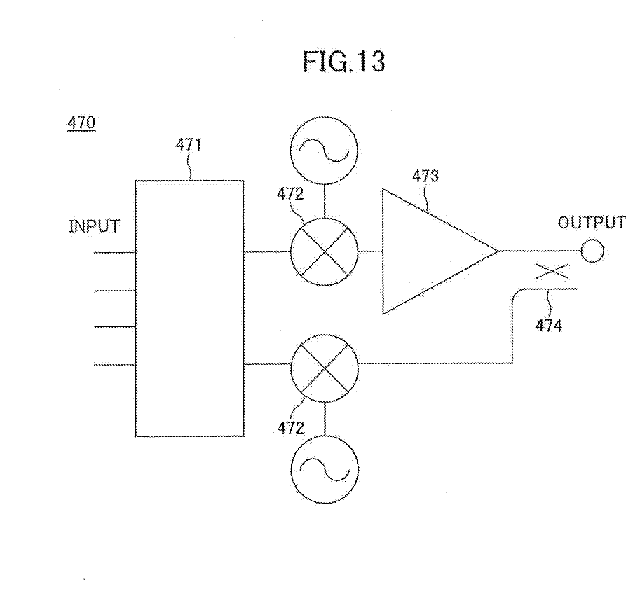

In the following, a description will be given of the high-frequency amplifier of the present embodiment by referring to FIG. 13. A high-frequency amplifier 470 of the present embodiment may be used as a power amplifier in a mobile-phone base station, for example. The high-frequency amplifier 470 includes a digital pre-distortion circuit 471, mixers 472, a power amplifier 473, and a directional coupler 474. The digital pre-distortion circuit 471 reduces the nonlinear distortion of an input signal. Each of the mixers 472 mixes the input signal having a reduced nonlinear distortion with an alternating-current signal. The power amplifier 473 amplifies the input signal that is mixed with the alternating-current signal. In the example illustrated in FIG. 13, the power amplifier 473 includes the semiconductor devices of the first or second embodiment. The directional coupler 474 is used to monitor the input signal and the output signal. In the circuit illustrated in FIG. 13, switching is performed, for example, so that an output signal is mixed by one of the mixers 472 with an alternating-current signal for provision to the digital pre-distortion circuit 471.

According to the semiconductor device and the method of manufacturing a semiconductor device disclosed herein, a semiconductor device in which nitride semiconductor is formed on a silicon substrate or the like is obtained such that distortion in the silicon substrate or the like and cracks in the nitride semiconductor layers are suppressed, and such that satisfactory characteristics are achieved at low cost.

All examples and conditional language recited herein are intended for pedagogical purposes to aid the reader in understanding the invention and the concepts contributed by the inventor to furthering the art, and are to be construed as being without limitation to such specifically recited examples and conditions, nor does the organization of such examples in the specification relate to a showing of the superiority and inferiority of the invention. Although the embodiment(s) of the present inventions have been described in detail, it should be understood that the various changes, substitutions, and alterations could be made hereto without departing from the spirit and scope of the invention.

What is claimed is:

1. A semiconductor device, comprising:
a buffer layer made of nitride semiconductor on a substrate;
a first semiconductor layer made of nitride semiconductor on the buffer layer;
a second semiconductor layer made of nitride semiconductor on the first semiconductor layer; and
a gate electrode, a source electrode, and a drain electrode formed on the second semiconductor layer,
wherein the buffer layer has elements doped therein that include both an element selected from a group consisting of C, Mg, Fe, and Co and an element selected from a group consisting of Si, Ge, Sn, and O.

2. The semiconductor device as claimed in claim 1, wherein the element doped in the buffer layer and selected from the group consisting of Si, Ge, Sn, and O has density thereof increasing toward the first semiconductor layer from a side thereof facing the substrate.

3. The semiconductor device as claimed in claim 1, wherein the buffer layer includes a first buffer layer situated toward to the substrate and a second buffer layer situated away from the substrate, and density of the element selected from the group consisting of Si, Ge, Sn, and O is higher in the second buffer layer than in the first buffer layer.

4. The semiconductor device as claimed in claim 1, wherein the element doped in the buffer layer and selected from the group consisting of C, Mg, Fe, and Co has homogeneous density.

5. The semiconductor device as claimed in claim 1, wherein the buffer layer is made of AlₓGa₁₋ₓN.

6. The semiconductor device as claimed in claim 5, wherein x is larger than or equal to 0 and smaller than or equal to 0.5.

7. The semiconductor device as claimed in claim 1, wherein C is doped in the buffer layer, and density of C doped in the buffet layer is larger than or equal to 1.0×10¹⁶ atoms/cm³ and smaller than or equal to 1.0×10¹⁸ atoms/cm³.

8. The semiconductor device as claimed in claim 1, wherein Si is doped in the buffer layer, and density of Si doped in the buffer layer is, at a highest density point thereof, larger than or equal to 1.0×10¹⁸ atoms/cm³ and smaller than or equal to 1.0×10²⁰ atoms/cm³.

9. The semiconductor device as claimed in claim 1, wherein Si and C are doped in the buffer layer.

10. The semiconductor device as claimed in claim 1, wherein the substrate is made of one of Si, SiC, and sapphire.

11. The semiconductor device as claimed in claim 1, further comprising a nucleation layer made of material inclusive of AlN and situated between the substrate and the buffer layer.

12. The semiconductor device as claimed in claim 1, wherein the first semiconductor layer is made of material inclusive of GaN.

13. The semiconductor device as claimed in claim 1, wherein the second semiconductor layer is made of material inclusive of AlGaN.

14. The semiconductor device as claimed in claim 1, further comprising a third semiconductor layer made of n-type nitride semiconductor on the second semiconductor layer, wherein the gate electrode, the source electrode, and the drain electrode are formed on the third semiconductor layer.

15. The semiconductor device as claimed in claim 14, wherein the third semiconductor layer is made of material inclusive of n-GaN.

16. A power supply apparatus comprising the semiconductor device of claim 1.

17. An amplifier comprising the semiconductor device of claim 1.

18. A method of manufacturing a semiconductor device, comprising:
forming a buffer layer made of nitride semiconductor on a substrate;
forming a first semiconductor layer made of nitride semiconductor on the buffer layer;
forming a second semiconductor layer made of nitride semiconductor on the first semiconductor layer; and
forming a gate electrode, a source electrode, and a drain electrode on the second semiconductor layer,
wherein the buffer layer has elements doped therein that include both an element selected from a group consisting of C, Mg, Fe, and Co and an element selected from a group consisting of Si, Ge, Sn, and O.
